(19) United States
(12) Patent Application Publication
(10) Pub. No.: US 2005/0039889 A1
(43) Pub. Date: Feb. 24, 2005

(54) Phase transformation heat dissipation apparatus

(76) Inventor: Yu-Nien Huang, Chung Li City (TW)

Correspondence Address: RABIN & BERDO, P.C.;Suite 500, 1101 14 Street, N.W., Washington, DC, 20005, US

(21) Appl. No.: 10/891,128

(22) Filed: Jul. 15, 2004

(30) Foreign Application Priority Data
Aug. 8, 2003 (TW) 92121918

(51) Int. Cl. H05K 7/20

(52) U.S. Cl. 165/104.33

(57) ABSTRACT

A phase transformation heat dissipation apparatus is described. The apparatus has a heat exchange device, a gaseous fluid transmission tube, a heat exchange chamber, a storage container and a liquid fluid transmission tube. The heat exchange device couples to a heat source to dissipate heat generated by the heat source with a fluid during a phase transformation thereof. A gaseous fluid is transferred to the heat exchange chamber by way of the gaseous fluid transmission tube and is condensed back into liquid fluid. The liquid fluid drops into the storage container and is utilized to remove the heat generated by the heat source again. The apparatus further has a capillary structure to provide the liquid fluid for the heat exchange device and furthermore has flexible tubes to connect the heat exchange chamber disposed in a liquid crystal display to the heat exchange device disposed in a notebook computer base.

### FIELD OF THE INVENTION

The present invention relates to a phase transformation heat dissipation apparatus, and especially, to a phase transformation heat dissipation apparatus for a notebook computer.

### BACKGROUND OF THE INVENTION

Information technology and the computer industry are highly developed now. Portable electronic devices, such as notebook computers, are widely used. Due to weight and practical requirements, portable devices tend to be lighter, thinner, shorter or smaller as possible. The notebook computer is a successful product because the notebook computer with powerful calculation capability deals with a great amount of digital data.

Because the semiconductor manufacture process has highly progressed and functional requirements of the semiconductor are highly intense, the electric circuit layout of the semiconductor becomes more complicated and more sophisticated. For example, an electric circuit layout of a new generation central processing unit (CPU) is more complicated because the new generation CPU has to provide more powerful functions for users and application software. The new generation CPU provides powerful functions and performance but the more powerful CPU generates new problems in use. A serious problem is that the new generation CPU with a complicated circuit has higher power consumption and thus severely elevates the working temperature of the chips. The high working temperature can cause instability in a working system, and especially in a small-sized portable device. In general, a lower working temperature makes a portable device more stable. That is to say, if the working temperature of a notebook computer can be kept low, the performance thereof is high. On the contrary, if the working temperature is too high, the performance and stability will decrease and the operation system may even crash, in some extreme situations.

Conventionally, a heat dissipation device directly disposed on the CPU having high power consumption exhausts the heat generated by the CPU. A fan of the heat dissipation device blows on heat dissipation fins to exhaust the heat of the CPU out of the computer. The conventional heat dissipation device can exhaust part of the heat generated by the CPU. However, the conventional heat dissipation device is not enough to exhaust the heat generated by the new generation computer with higher power consumption due to the daily power consumption increase. Furthermore, the fan itself also generates quite a lot of heat and noise because a high power cooling fan is used to cool the new generation CPU. The efficiency of the heat dissipation is therefore reduced.

### SUMMARY OF THE INVENTION

One object of the present invention is to provide a phase transformation heat dissipation apparatus to enhance a heat dissipation efficiency for a central processing unit.

Another object of the present invention is to provide a phase transformation heat dissipation apparatus to reduce efficiently a working temperature of a notebook computer.

A further object of the present invention is to utilize phase transformation and gravity circulation to remove heat generated by a heat source and maintain a suitable working temperature without any electrical power requirement.

To achieve these and other advantages and in accordance with the purpose of the present invention, as embodiment and broadly described herein, the present invention provides a phase transformation heat dissipation apparatus. The phase transformation heat dissipation apparatus has a heat exchange device, a gaseous fluid transmission tube, a heat exchange chamber, a storage container, and a liquid fluid transmission tube. The heat exchange device is coupled to a heat source to remove a heat generated by the heat source. The heat exchange device utilizes a liquid fluid to absorb the heat and therefore the liquid fluid vaporizes into a gaseous fluid. The gaseous fluid is then transferred to the heat exchange chamber by way of the gaseous fluid transmission tube. In the heat exchange chamber, the gaseous fluid is condensed and returned back to the liquid fluid to remove the heat from the heat exchange chamber.

The liquid fluid naturally gravitationally drops to a bottom of the heat exchange chamber with an incline and is stored in the storage container under the heat exchange chamber. The liquid fluid is then transferred to the heat exchange device again by way of the liquid fluid transmission tube. The liquid fluid transmission tube further utilizes a liquid fluid provider with a capillary structure to delivery the liquid fluid to the heat exchange device.

The capillary structure is a lamp wick structure, porous sintered wire meshes, micro grooves, or micro meshes. The heat exchange chamber is a flat heat exchange chamber or a tubular heat exchange chamber.

In another aspect, the present invention provides a notebook computer with a phase transformation heat dissipation apparatus. The notebook computer has a liquid crystal display, a computer base, a central processing unit, a hinge, and a phase transformation heat dissipation apparatus. The central processing unit, a heat source, is configured in the computer base. The phase transformation heat dissipation apparatus is utilized to remove a heat generated by the heat source. A heat exchange device of the phase transformation heat dissipation apparatus is disposed in the computer base, and the heat exchange chamber of the phase transformation heat dissipation apparatus is disposed in a rear side of the liquid crystal display. Flexible tubes are utilized to couple to the heat exchange device and the heat exchange chamber, and therefore the liquid crystal display of the notebook computer can easily open and close. The heat exchange device of the phase transformation heat dissipation apparatus can be easily installed in a current computer base due to a small occupation area.

Hence, the present invention utilizes a natural gravity circulation to remove the heat generated by the heat source and furthermore a phase transformation to increase the heat dissipation efficiency. Therefore, the present invention can work without any additional electrical power and pump to cool down an electric product with a quiet heat dissipation circulation. For a notebook computer, the present invention can utilize a current computer base and attach the heat exchange chamber to the rear side of the liquid crystal display to decrease the temperature of the central processing unit without the noise of a cooling fan.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 is a schematic view of a preferred embodiment of a phase transformation heat dissipation apparatus according to the present invention.

### DETAILED DESCRIPTION OF THE PREFERRED EMBODIMENT

The following description is of the best presently contemplated mode of carrying out the present invention. This description is not to be taken in a limiting sense but is made merely for the purpose of describing the general principles of the invention. The scope of the invention should be determined by referencing the appended claims.

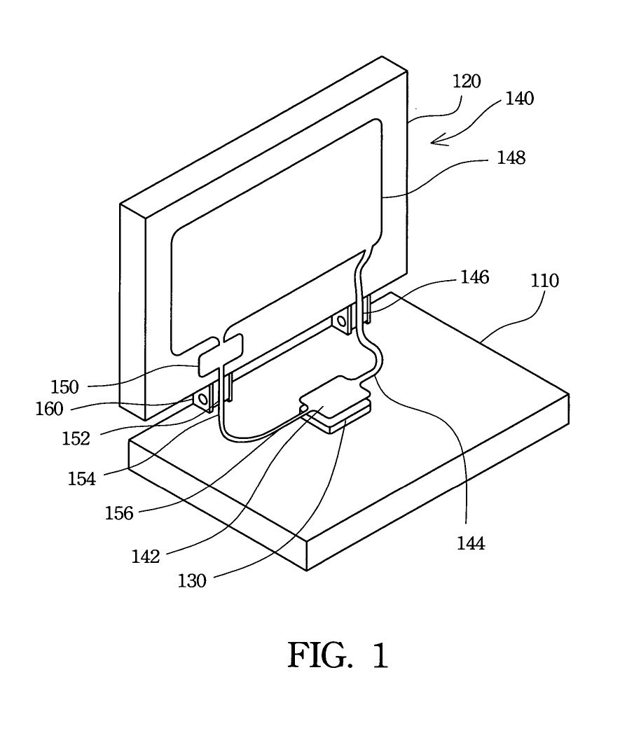

FIG. 1 is a schematic view of a preferred embodiment of a phase transformation heat dissipation apparatus according to the present invention. The preferred embodiment utilizes a notebook computer to describe the advantages of the phase transformation heat dissipation apparatus. The exemplary notebook computer includes a computer base 110, liquid crystal display 120, and hinge shaft 160. The hinge shaft 160 couples the liquid crystal display 120 to the computer base 110 and the liquid crystal display 120 can therefore rotate on the computer base 110 by using the hinge shaft 160 as an axis. A phase transformation heat dissipation apparatus 140 is disposed between a central processing unit 130 and the liquid crystal display 120 to absorb heat generated by the central processing unit 130 with a latent heat change caused by a phase transformation. The heat is then dissipated by a heat exchange chamber 148 having a large volume and disposed in the liquid crystal display 120. Accordingly, the heat generated by the central processing unit 130 can be removed efficiently by the phase transformation heat dissipation apparatus 140.

The phase transformation heat dissipation apparatus 140 has a heat exchange device 142, a gaseous fluid transmission tube 144, a flexible tube 146, the heat exchange chamber 148, a storage container 150, a flexible tube 152, and a liquid fluid transmission tube 154. The liquid fluid transmission tube 154 further has a liquid fluid provider 156 to transfer a liquid fluid to the heat exchange device 142 disposed on central processing unit 130 with a capillarity effect. The liquid fluid is then vaporized into a gaseous fluid. Therefore, the fluid absorbs a great amount of heat generated by the central processing unit 130 due to the latent heat change caused by the phase transformation. Because a specific heat of the latent heat change caused by phase transformation is greater than a specific heat of a fluid working in single phase, the phase transformation heat dissipation apparatus 140 can absorb more heat than a conventional heat dissipation apparatus.

After the liquid fluid is vaporized into the gaseous fluid by the heat exchange device 142, the gaseous fluid is delivered to the heat exchange chamber 148 in the liquid crystal display 120 by way of the gaseous fluid transmission tube 144 and the flexible tube 146. The flexible tube 146 is configured from the computer base 110 to the liquid crystal display 120 along the hinge shaft 160. The flexible tube 146, such as, for example, a flexible pneumatic pipe, is a tube delivering the fluid is not deformed, such as expansion or shrinking when rotated or bent under high pressure. The flexible tube 146 is preferably disposed along a center of the hinge shaft 160 or parallel to the hinge shaft 160 to the liquid crystal display 120.

The gaseous fluid arrived the heat exchange chamber 148 is condensed in the heat exchange chamber 148 disposed on the rear side of the liquid crystal display 120. The heat exchange chamber 148 is a very large heat exchange chamber with large area, especially compared with the heat exchange device 142, to exchange the heat with outer air. The heat exchange chamber 148 therefore provides an extremely large heat dissipation area to cool down the gaseous fluid back to the liquid fluid. Accordingly, the gaseous fluid can efficiently condense to the liquid fluid and release the latent heat from the notebook computer.

The heat exchange chamber 148 with a large heat dissipation area can be formed by a flat heat exchange chamber, an interlaced tubular heat exchange chamber, or a zigzag tubular heat exchange chamber. For example, the heat exchange chamber 148 is formed by a circuitous heat dissipation pipe from the top of the liquid crystal display 120 to the bottom of the liquid crystal display 120 or a circuitous heat dissipation pipe from the right side with a slight tilt downward toward the left side. The phase transformation heat dissipation apparatus 140 according to the present invention can utilize any kind of heat exchange chamber 148 with a large heat dissipation area compared with the heat exchange device 142 to remove efficiently the heat generated by the central processing unit 130.

The condensed liquid fluid is stored in the storage container 150 and an incline is further formed at the bottom of the heat exchange chamber 148 for collecting the condensed liquid fluid easily. The liquid fluid may accordingly drop to the bottom of the heat exchange chamber 148 due to gravity and then is stored in the storage container 150 by way of the incline.

After the storage container 150 collects the condensed liquid fluid, the condensed liquid fluid is transferred to the heat exchange device 142 for cooling down the central processing unit 130 again. The liquid fluid in the storage container 150 is delivered to the heat exchange device 142 by way of the liquid fluid transmission tube 154 and the flexible tube 152. Near the hinge shaft 160, the liquid fluid transmission tube 154 delivers the liquid fluid from the rear side of the liquid crystal display 120 into the computer base 110. The flexible tube 152, such as, for example, a flexible hydraulic tube, can rotate and bend according to the rotation of the hinge shaft 160 without deformation, and withstand the pressure difference between the inside and outside of the flexible tube 152. The flexible tube 152 is preferably disposed on the computer base 110 along a center of the hinge shaft 160 or parallel to the hinge shaft 160.

Because the gaseous fluid is delivered from the heat exchange device 142 in the computer base 110 to the heat exchange chamber 148 in the liquid crystal display 120 and the liquid fluid is delivered from the heat exchange chamber 148 to the heat exchange device 142, the gaseous fluid transmission tube 144 is preferably accomplished with a larger diameter tube than the liquid fluid transmission tube 154.

The liquid fluid provider 156 includes a lamp wick structure for absorbing the liquid fluid and supplying the same to the heat exchange device 142 when the liquid fluid arrives in the liquid fluid provider 156. The liquid fluid is then vaporized into the gaseous fluid to remove the heat generated by the central processing unit 130 with the latent heat change of the phase transformation of the liquid fluid in the heat exchange device 142. The heat exchange device 142, the heat exchange chamber 148, and the gaseous fluid transmission tube 144 preferably maintain a low working pressure, and therefore the liquid fluid can easily reach a phase transformation temperature thereof. The liquid fluid provider 156 utilizes a capillary structure such as, for example, the lamp wick structure, micro grooves, micro meshes, or porous sintered wire meshes, to transfer the liquid fluid to the heat exchange device 142 and keep efficiently the low pressure in the heat exchange device 142.

The fluid can be, for example, methyl alcohol, water or any other material with a phase transformation, according to the practical working requirement. Any fluid with the phase transformation effect meeting the practical working temperature and pressure range can be utilized in the phase transformation heat dissipation apparatus 140.

The phase transformation heat dissipation apparatus according to the present invention utilizes the phase transformation phenomenon to remove efficiently the heat generated by a heat source, the gravity circulation to transfer efficiently the liquid fluid back to the storage container, and the capillary effect to provide automatically the liquid fluid to the heat exchange device and keep the required pressure therein. Therefore, the phase transformation heat dissipation apparatus according to the present invention can work without any additional electrical power. Furthermore, the power consumption of a notebook computer with the phase transformation heat dissipation apparatus can be reduced and a computer without a noisy fan can be achieved. Since the volume of the phase transformation heat dissipation apparatus inside the computer base is very small, the phase transformation heat dissipation apparatus is convenient to install in a current computer base. It is noted that the aforementioned phase transformation heat dissipation apparatus of the present invention utilized in a notebook computer is merely stated as an example, and the scope of the present invention is not limited thereto. Other electric and computer products can also utilize the phase transformation heat dissipation apparatus of the present invention to reduce the power consumption and noise thereof.

As is understood by a person skilled in the art, the foregoing preferred embodiments of the present invention are illustrative of the present invention rather than limiting of the present invention. It is intended that various modifications and similar arrangements be included within the spirit and scope of the appended claims, the scope of which should be accorded the broadest interpretation so as to encompass all such modifications and similar structures.

1. A phase transformation heat dissipation apparatus for a notebook with a heat source, comprising:
a heat exchange device coupled to the heat source to remove a heat generated by the heat source, the heat exchange device utilizing a liquid fluid and a gaseous fluid, wherein the liquid fluid absorbs the heat and vaporizes into the gaseous fluid;
a gaseous fluid transmission tube coupled to the heat exchange device for transferring the gaseous fluid;
a heat exchange chamber coupled to the gaseous fluid transmission tube, the gaseous fluid being transferred to the heat exchange chamber by way of the gaseous fluid transmission tube, wherein the gaseous fluid is condensed into the liquid fluid for removing the heat in the heat exchange chamber;
a storage container coupled to the heat exchange chamber and under the heat exchange chamber for collecting the liquid fluid; and
a liquid fluid transmission tube coupled between the storage container and the heat exchange device for transferring the liquid fluid to the heat exchange device.

2. The phase transformation heat dissipation apparatus of claim 1, wherein the liquid fluid transmission tube further comprises a liquid fluid provider to deliver the liquid fluid to the heat exchange device.

3. The phase transformation heat dissipation apparatus of claim 2, wherein the liquid fluid provider further comprises a capillary structure.

4. The phase transformation heat dissipation apparatus of claim 3, wherein the capillary structure comprises porous sintered wire meshes.

5. The phase transformation heat dissipation apparatus of claim 3, wherein the capillary structure comprises micro grooves.

6. The phase transformation heat dissipation apparatus of claim 3, wherein the capillary structure comprises micro meshes.

7. The phase transformation heat dissipation apparatus of claim 1, wherein the gaseous fluid transmission tube further comprises a flexible tube to prevent shrinkage or expansion when the gaseous fluid transmission tube bends and rotates.

8. The phase transformation heat dissipation apparatus of claim 1, wherein the heat exchange chamber comprises a flat heat exchange chamber.

9. The phase transformation heat dissipation apparatus of claim 1, wherein the heat exchange chamber comprises a zigzag tubular heat exchange chamber.

10. The phase transformation heat dissipation apparatus of claim 1, wherein the heat exchange chamber further comprises an incline to collect the liquid fluid.

11. The phase transformation heat dissipation apparatus of claim 1, wherein the heat exchange device is utilized to cool down a central processing unit of a notebook computer.

12. A phase transformation heat dissipation apparatus for a notebook computer with a base, a display module and a heat source, comprising:
a heat exchange device coupled to the heat source on the base to remove a heat generated by the heat source, the heat exchange device utilizing a liquid fluid and a gaseous fluid, wherein the liquid fluid absorbs the heat and vaporizes into the gaseous fluid;
a gaseous fluid transmission tube coupled to the heat exchange device for transferring the gaseous fluid;
a heat exchange chamber coupled to the gaseous fluid transmission tube and disposed on the display module, the heat exchange chamber comprising an incline, and the gaseous fluid being transferred to the heat exchange chamber by way of the gaseous fluid transmission tube, wherein the gaseous fluid is condensed into the liquid fluid for removing heat in the heat exchange chamber;
a storage container coupled to the incline of the heat exchange chamber and under the heat exchange chamber for storing the liquid fluid collected by the incline;
a liquid fluid transmission tube coupled to the storage container; and
a liquid fluid provider coupled between the liquid fluid transmission tube and the heat exchange device, wherein the liquid fluid provider further comprises a capillary structure for delivering the liquid fluid to the heat exchange device.

13. The phase transformation heat dissipation apparatus of claim 12, wherein the capillary structure comprises porous sintered wire meshes.

14. The phase transformation heat dissipation apparatus of claim 12, wherein the capillary structure comprises micro grooves.

15. The phase transformation heat dissipation apparatus of claim 12, wherein the heat exchange chamber comprises a flat heat exchange chamber.

16. The phase transformation heat dissipation apparatus of claim 12, wherein the heat exchange chamber comprises a zigzag tubular heat exchange chamber.

17. A notebook computer with a phase transformation heat dissipation apparatus, the notebook computer comprising:
a liquid crystal display;
a computer base;
a central processing unit configured in the computer base;
a hinge coupling between the liquid crystal display and the computer base; and
a phase transformation heat dissipation apparatus, the phase transformation heat dissipation apparatus further comprising:
a heat exchange device coupled to the central processing unit to remove heat generated by the central processing unit, the heat exchange device utilizing a liquid fluid and a gaseous fluid to remove the heat, wherein the liquid fluid absorbs the heat and vaporizes into the gaseous fluid;
a gaseous fluid transmission tube coupled to the heat exchange device to transfer the gaseous fluid;
a first flexible tube coupled to the gaseous fluid transmission tube and disposed between the liquid crystal display and the computer base;
a heat exchange chamber disposed on a rear side of the liquid crystal display and coupled to the first flexible tube, the heat exchange chamber comprising an incline, and the gaseous fluid being transferred to the heat exchange chamber by way of the gaseous fluid transmission tube and the first flexible tube, wherein the gaseous fluid is condensed into the liquid fluid to remove heat generated by the central processing unit in the heat exchange chamber;
a storage container coupled to the incline of the heat exchange chamber and under the heat exchange chamber to store the liquid fluid collected by the incline;
a liquid fluid transmission tube coupled to the storage container;
a second flexible tube coupled to the liquid fluid transmission tube and disposed between the liquid crystal display and the computer base; and
a liquid fluid provider coupled between the second flexible tube and the heat exchange device, wherein the liquid fluid provider further comprises a capillary structure to delivery the liquid fluid to the heat exchange device.

18. The phase transformation heat dissipation apparatus of claim 17, wherein the capillary structure comprises porous sintered wire meshes, micro grooves or porous sintered wire meshes.

19. The phase transformation heat dissipation apparatus of claim 17, wherein the heat exchange chamber comprises a flat heat exchange chamber.

20. The phase transformation heat dissipation apparatus of claim 17, wherein the heat exchange chamber comprises a zigzag tubular heat exchange chamber.
